(19) United States
(12) Patent Application Publication
(10) Pub. No.: US 2023/0394190 A1
(43) Pub. Date: Dec. 7, 2023

(54) METHOD AND SYSTEM TO MITIGATE AQUAPLANING

(71) Applicant: ZF Friedrichshafen AG, Friedrichshafen (DE)

(72) Inventors: David WILSON, Milford, MI (US); Pulkit MONGA, Westland, MI (US); Srinivas MYSORE, Novi, MI (US)

(21) Appl. No.: 18/329,170

(22) Filed: Jun. 5, 2023

Related U.S. Application Data
(60) Provisional application No. 63/349,307, filed on Jun. 6, 2022.

(51) Int. Cl. G06F 30/15

(52) U.S. Cl. CPC G06F 30/15

(57) ABSTRACT

A method of mitigating aquaplaning by a vehicle is disclosed. The method comprises creating an aquaplaning identification model using simulated data and deploying the model in a vehicle onboard computer. During vehicle operation, data is collected from one or more image sensors installed on the vehicle and directed to the model disposed on the onboard computer. The results of the model are deployed to a server cloud wherein the results are processed in a neural net and the model is updated in the server cloud and an updated model is deployed to the vehicle onboard computer in a software loop. The method of developing the model is also disclosed.

### CROSS-REFERENCE TO RELATED APPLICATIONS

This application claims the benefit of U.S. Provisional application Ser. No. 63/349,307 filed Jun. 6, 2022, the disclosure of which is hereby incorporated in its entirety by reference herein.

### TECHNICAL FIELD

The present disclosure relates to utilizing image sensor technology to develop and train a computer model to utilize captured sensor data capture and feed such data into the computer-trained model to determine if liquid is present on a roadway that may lead to aquaplaning. In addition, the disclosure is also related to determining various characteristics of such liquid.

### BACKGROUND

Aquaplaning, also referred to as hydroplaning, is a condition where a layer of water or other liquid builds up between the wheels of a vehicle and the road surface, causing the wheels to “float” on the liquid, leading to a loss of traction with the ground surface. As a result of the loss of traction, because every vehicle function that changes direction or speed relies on friction between the wheels and road surface, no steering or braking forces can be transferred to the ground surface. Thus, a significant risk to the operation of the vehicle is created during aquaplaning.

Indeed, the risk to the operation of the vehicle is further exacerbated during an aquaplaning event is that in many instances, the aquaplaning event occurs without any significant advance warning that can identified by a vehicle driver, thus causing the driver to be surprised by the event and unable to avoid the liquid on the ground surface.

Since liquid on the ground surface represents a driving hazard, potentially leading to loss of control and accident, what is needed is the ability to identify a risk of aquaplaning as early as possible. For example, it would be desirable if upfront knowledge of liquid on the ground surface would allow for a choice of mitigating strategies, including avoidance, initialization of a control unit (with communication to an antilock braking system, steering, etc.), or even preparing for an anticipated accident with advance communication to an occupant safety system, such as airbag, seatbelts, emergency calling features, etc.

### SUMMARY

A method of developing an aquaplaning mitigation model is disclosed. The method comprises creating a virtual dataset with simulated data that includes one or more liquid obstacles disposed on a simulated roadway. A vehicle is instrumented with one or more sensors and configured to detect a liquid obstacle on an actual roadway in real-time. Ground truth data concerning detected liquid obstacles on the actual roadway is collected by performing an initial vehicle operation. As the vehicle operation continues, the simulated data is replaced with the collected ground truth data to buildout a liquid obstacle database.

The simulated data and ground truth data are transmitted to a neural net to define a model for identifying liquid obstacles. The neural net processes the transmitted data to identify predetermined characteristics of a liquid obstacle to create rules for classifications within the transmitted data. Additional vehicle operations are performed over the actual road and ground truth data is continuously collected during the additional vehicle operations. The collected ground truth data collected during the second vehicle operation is transmitted into the neural net to train the model until the model is validated. Once validated the model is deployed to the vehicle and data is continuously collected during subsequent driving operations. The continuously collected data is transmitted to the neural net to further improve and update the model.

A method of mitigating aquaplaning by a vehicle is disclosed. The method comprises creating an aquaplaning identification model using simulated data and deploying the model in a vehicle onboard computer. During vehicle operation, data is collected from one or more image sensors installed on the vehicle and directed to the model disposed on the onboard computer. The results of the model are deployed to a server cloud wherein the results are processed in a neural net and the model is updated in the server cloud and an updated model is deployed to the vehicle onboard computer in a software loop.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompany drawings in which:

FIG. 1 illustrates a block diagram for an aquaplaning system in an automotive application;

FIG. 2 is a flow chart that illustrate an example process for generating of a dataset for use in a model for determining if a liquid is present on a roadway in real time;

FIG. 3 is a schematic arrangement of a system for utilizing a model for detection of aquaplaning in real time;

FIG. 4 is a schematic of an aquaplaning system across a fleet of vehicles;

FIG. 5 is a flow chart that illustrates an example process for the aquaplaning system described in FIGS. 1 and 3; and

FIG. 6 is a flow chart that illustrates an example process for another example of a set up and training phase of the process of FIG. 5; and

FIG. 7 is a flow chart that illustrates an example process for another example of a deployment phase of FIG. 5.

### DETAILED DESCRIPTION

Referring now to the discussion that follows, and to the drawings, illustrative approaches to the disclosed systems and methods are shown in detail. Although the drawings represent some possible approaches, the drawings are not necessarily to scale and certain features may be exaggerated, removed, or partially sectioned to better illustrate and explain the present disclosure. Further, the descriptions set forth herein are not intended to be exhaustive or otherwise limit or restrict the claims to the precise forms and configurations shown in the drawings and disclosed in the following detailed description.

Disclosed herein is an aquaplaning mitigation system configure to detect liquid such as water, oil, etc., as well as snow and ice, on a roadway, share such detection across a fleet of vehicles, and deploy appropriate vehicle systems and alerts to increase vehicle capabilities. In one example, a vehicle may generate synthetic data to create a baseline data set. As the vehicle is operated and acquires real-world data of the roadways, data is acquired from the vehicle sensors (including lidar sensors, cameras, etc.). This data may be sent to a computer-trained model to determine whether liquid is present on the road, and if so, certain parameters of the liquid obstacle, such as size, location, area on the road (left lane vs. right lane), etc. In response to such ground truth detecting liquid on a roadway, the vehicle may then transmit such data to a cloud for other vehicles to receive. Upon receiving this information, the respective vehicles may determine whether the vehicle is approaching the identified liquid object and determine whether to deploy or activate certain vehicle systems such as traction control, or issue any alerts to the driver.

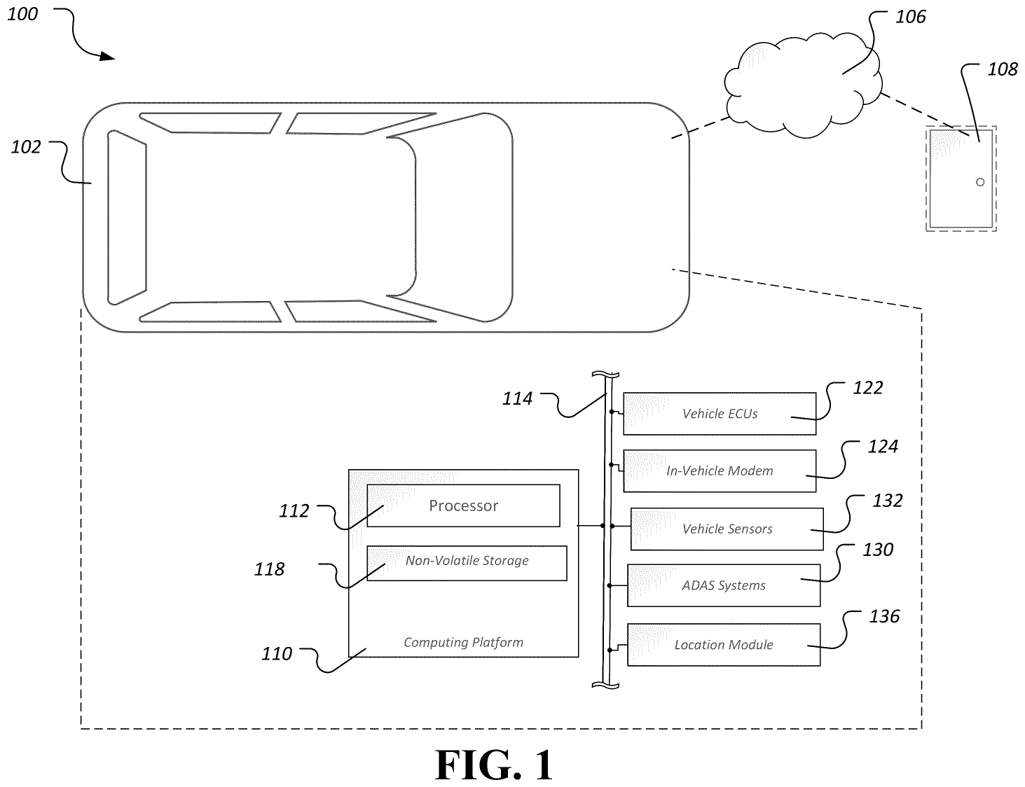

FIG. 1 illustrates a block diagram for an aquaplaning system 100 in an automotive application. The aquaplaning system 100 may be designed for a vehicle 102 configured to transport passengers. The vehicle 102 may include various types of passenger vehicles, such as crossover utility vehicle (CUV), sport utility vehicle (SUV), truck, recreational vehicle (RV), or other mobile machine for transporting people or goods.

The vehicle 102 may be autonomous, partially autonomous, self-driving, driverless, or driver-assisted vehicles. The vehicle 102 may be an electric vehicle (EV), such as a battery electric vehicle (BEV), plug-in hybrid electric vehicle (PHEV), hybrid electric vehicle (HEVs), etc. The vehicle 102 may be configured to include various types of components, processors, and memory, and may communicate with a communication network 106. The communication network 106 may be referred to as a “cloud” and may involve data transfer via wide area and/or local area networks, such as the Internet, global navigation satellite system (GNSS), cellular networks, Wi-Fi, Bluetooth, etc. The communication network 106 may provide for communication between the vehicle 102 and an external or remote server 108 and/or database, as well as other external applications, systems, vehicles, etc. This communication network 106 may provide data and/or services to the vehicle 102 such as navigation, music or other audio, program content, marketing content, software updates, system updates, Internet access, speech recognition, cognitive computing, artificial intelligence, etc.

The communication network 106 may also provide for communication among vehicles in a vehicle-to-vehicle communication system. Vehicles may be part of a “fleet” and may share data and information to further provide for an enhanced driver experiences. In one example, if one vehicle gathers data, such data may be shared and used by other vehicles. This is discussed in more detail herein with respect to the identified liquid objects on roadways for aquaplaning mitigation.

The remote server 108 may include one or more computer hardware processors coupled to one or more computer storage devices for performing steps of one or more methods as described herein (not shown). These hardware elements of the remote server 108 may enable the vehicle 102 to communicate and exchange information and data with systems and subsystems external to the vehicle 102 and local to or onboard the vehicle 102. The vehicle 102 may include a computing platform 110 having one or more processors 112 configured to perform certain instructions, commands and other routines as described herein. Internal vehicle networks 114 may also be included, such as a vehicle controller area network (CAN), an Ethernet network, and a media oriented system transfer (MOST), etc. The internal vehicle networks 114 may allow the processor 112 to communicate with other vehicle systems, such as an in-vehicle modem 124, and various vehicle electronic control units (ECUs) 122 configured to corporate with the processor 112.

The processor 112 may execute instructions for certain vehicle applications, including aquaplaning monitoring, navigation, infotainment, climate control, etc. Instructions for the respective vehicle systems may be maintained in a non-volatile manner using a variety of types of computer-readable storage medium 118. The computer-readable storage medium 118 (also referred to herein as memory 118, or storage) includes any non-transitory medium (e.g., a tangible medium) that participates in providing instructions or other data that may be read by the processor 112. Computer-executable instructions may be compiled or interpreted from computer programs created using a variety of programming languages and/or technologies, including, without limitation, and either alone or in combination, Java, C, C++, C#, Objective C, Fortran, Pascal, Java Script, Python, Perl, and PL/structured query language (SQL).

Vehicle ECUs 122 may be incorporated or configured to communicate with the computing platform 110. As some non-limiting possibilities, the vehicle ECUs 122 may include a powertrain control system, a body control system, a radio transceiver module, a climate control management system, human-machine interface (HMI)'s, etc. The in-vehicle modem 124 may be included to communicate information between the computing platform 110, the vehicle 102, and the remote server 108. The memory 118 may maintain the data about the vehicle 102, as well as specific information gather from vehicle sensors 132.

The vehicle 102 may also include a wireless transceiver (not shown), such as a BLUETOOTH module, a ZIGBEE transceiver, a Wi-Fi transceiver, an IrDA transceiver, a radio frequency identification (RFID) transceiver, etc.) configured to communicate with compatible wireless transceivers of various user devices, as well as with the communication network 106.

The vehicle 102 may include various other sensors 132 and input devices as part of other vehicle systems that may also be used by the aquaplaning system. The sensors 132 may include various ones of imaging sensors configured to detect image data and/or object detection data. The imaging sensors may be configured to capture and detect objects external to the vehicle 102 and transmit the data to the server 108 via the communication network 106. In one example, the imaging sensors may be cameras configured to acquire images of an area adjacent the vehicle. The cameras may be arranged as a front of vehicle camera. However, rear cameras may also be used. In one example, the rear camera may be used to confirm identification of a liquid of the first camera.

The sensors 132 may acquire environment data about the vehicle as the vehicle 102 operates. The environment data may be real-time or near real-time data acquired as the vehicle drives around a path. Such environment data may be used as unsupervised data when applying the aquaplaning model. Such environment data may also include metadata from the vehicle such as speed, weight, tire pressure, dynamics, traffic from GPS, etc. Some of this metadata may also be received via the CAN, while others directly from the vehicle sensors 132.

Such sensors 132 may also include, LiDAR, a radio detection and ranging (RADAR), a laser detection and ranging (LADAR), a sound navigation and ranging (SONAR), ultrasonic sensors, one or more cameras (e.g., visible spectrum cameras, infrared cameras, etc.), temperature sensors, position sensors (e.g., global positioning system (GPS), etc.), location sensors, motion sensor, etc. The sensor data can include information that describes the location of objects within the surrounding environment of the vehicle 102. The sensor data may also include image data including an image or indication of an object or obstruction. In one example, the sensor data may detect a water puddle on the road that is located in the field of view of the vehicle 102 and thus detectable by at least one of the sensors 132.

The vehicle 102 may also include a location module 136 such as a GNSS or GPS module configured to provide current vehicle 102 location and heading information. Other location modules 136 may also be used to determine vehicle location and the location data may accompany the image data when transmitted to the server 108.

The server 108 may collect and aggregate the image data. In one example, the server 108 may determine a location of a certain object based on location data associated with the image data. For example, the vehicle 102 may drive past a puddle on the other side of the road. The image data may indicate the puddle, the size and location. The server 108 may maintain this data and create a map of detected puddles. That is, the vehicle 102 may collect data about its surrounding areas as the vehicle 102 drives along a route. This data is aggregated and to be used and applied by the server 108.

The vehicle 102 may include various advanced driver-assistance (ADAS) systems 130, configured to assist a driver of the vehicle 102. The ADAS systems 130 may include alerts, control over various systems such and antilock brakes, etc. Other ADAS systems 130 may include stability control, traction control, etc. Such systems may be activated and controlled, at least in part, based on data from the sensors 132. In one example, aquaplaning mitigation may be carried out by the ADAS systems 130 in order to avoid slipping on wet roadways. This is discussed in more detail herein.

Although not specifically shown in FIG. 1, the vehicle 102 may include various displays and user interfaces, including heads up displays (HUDs), center console displays, steering wheel buttons, etc. Touch screens may be configured to receive user inputs. Visual displays may be configured to provide visual outputs to the user including outputs related to certain ADAS features, puddle detection, etc. The vehicle 102 may include numerous other systems such as GNSS systems, HMI controls, video systems, etc.

Furthermore, while an automotive system is discussed in detail here, other applications may be appreciated. For example, similar functionally may also be applied to other, non-automotive cases, e.g. for commercial vehicles, including tractors, combines, dump trucks, excavators, all-terrain vehicles (ATVs), side-by-sides, three-wheel machines, e-bikes, etc.

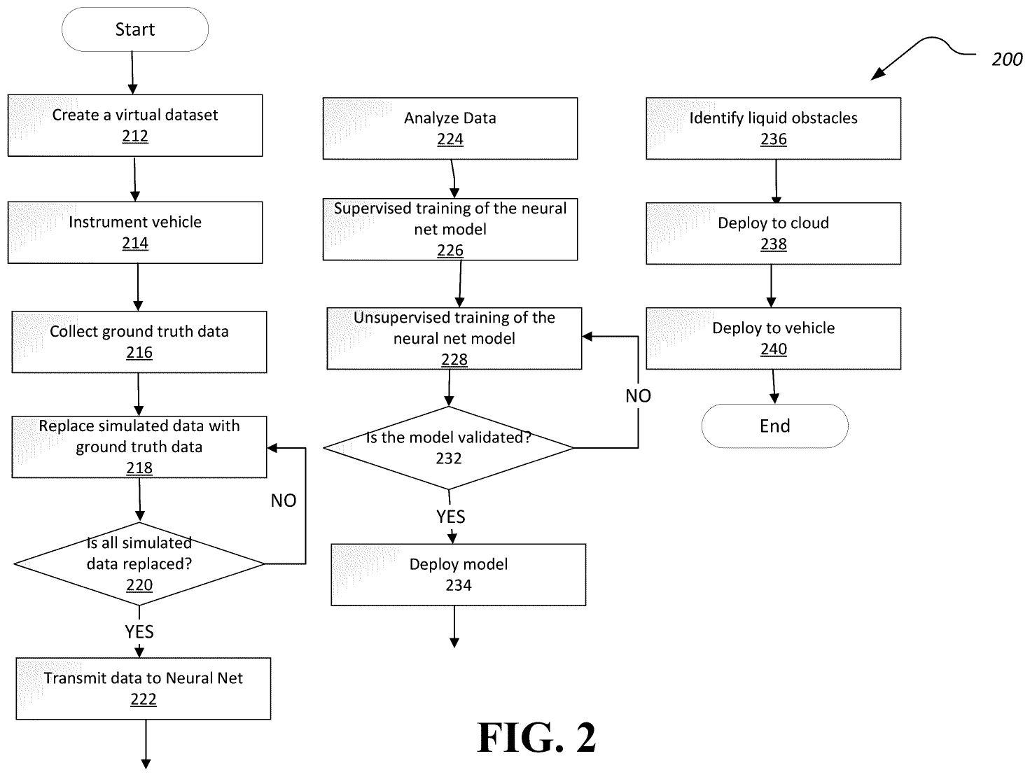

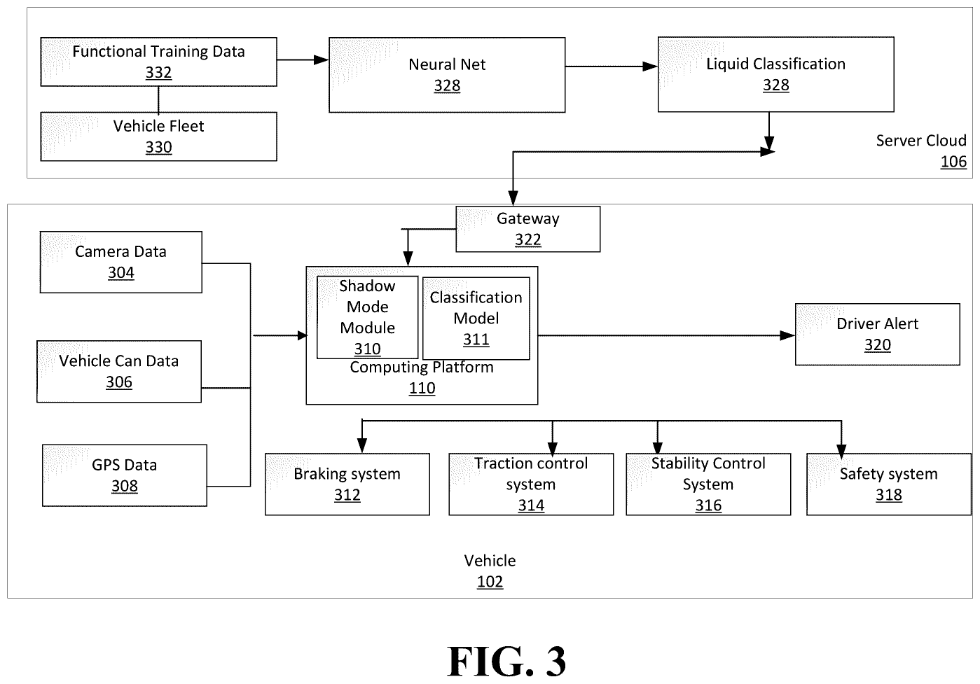

FIG. 2 illustrates an example process 200 for generating a dataset or database for use with a model for determining if a liquid is present on a roadway in real time, is illustrated. The process 200 may be carried out by the processors and controllers of the server 108, but may also be carried out by other processors, including other remote processors as well as the processor 112 or computing platform 110 of FIGS. 1 and 3. In one example, for data acquired by the vehicle 102, the onboard processor 112 of that vehicle 102 may perform certain processes and data acquired by other fleet vehicles may be analyzed by the server 108 via the communication network 106.

The process 200 may begin at block 212 where the processor may create a first initial virtual dataset. The virtual dataset may contain simulated data concerning liquid on a simulated road surface, such as surface water, coupled with simulated sensor data detecting predefined characteristics concerning the surface water. Such characteristics may include, but are not limited to, width and length of the liquid. This may be determined based on a suspected reflection of light created by the liquid object or obstruction. In addition, the virtual dataset may also include geographic information concerning the virtual roadway. For example, the geographic information may include the location of the liquid, as well as its position on the road, i.e., adjacent the lane line, etc. The virtual dataset may be stored on a vehicle onboard computer 110, may be operatively transmitted to an external data service, such as the cloud server 108, or a combination of both.

Once the virtual dataset is complete, the process 200 proceeds to block 214, where the vehicle 102 is instrumented with various sensors designed to capture various ground truth data concerning at least the same roadway that the virtual dataset is directed to. More specifically, the vehicle(s) may undergo a controlled vehicle set up and calibration designed to capture key data for use in the method, to ensure collection of accurate and true data for development of a model of determining liquid on a road surface. In one exemplary arrangement, and as explained above, the sensors may include, but are not limited to and image sensor, such as a forward camera, side view cameras, or a lidar device. The image sensor is configured to capture the roadway scene data in front of the vehicle. The image sensor is operatively connected to a processing unit, i.e., either a vehicle onboard computer (i.e., computing platform 110) or a cloud-based computing system located externally from the vehicle (i.e., such as the cloud server 108).

Once the vehicle is instrumented, the process 200 proceeds to block 216, whereby the vehicle 102 is operated. As the vehicle 102 is operated and ground truth data is collected from the image sensor(s) 132 and transmitted to the appropriate data processing unit (i.e., processor 112). Other devices, such as a GPS device or location module 136, may also be employed to transmit positional data that can be correlated with the image sensor data. In one exemplary arrangement, the data may be collected from the sensors 132 in a tabulated form using different data parameters. The operation and concurrent collection of data may be collected at speeds that enable water-on-road detection. Such data collection may be made for both one-way and two-way traffic situations, as well as at various times of day such as duck, dawn, day, and night.

As part of the collection of ground truth data, the collected data undergoes a data pre-processing operation. More specifically, the collected data is reviewed and sanitized to “clean” the data such that the data collected corresponds to accurate readings from the sensors. For example, in one exemplary arrangement, “no data intervals,” such as data points where a sensor failed (i.e., zero data collected) may be removed to create a robust database and model. In other exemplary arrangements, data induced by noise is also filtered out. Once the data is cleaned up, the data is structured to create a training data set for a model via a liquid obstacle database. For example, the initial data set is utilized to assist a program in applying processing technologies, like neural networks to learn and produce sophisticated results, as will be explained in further detail below.

At block 218, the ground truth data from block 216 is incorporated into the virtual dataset and replaces the simulated data from block 212 in the virtual dataset, thereby updating the dataset with data in real-time.

In one exemplary arrangement, at block 220, the collection of ground truth data and replacement of simulated data continues as the vehicle 102 is operated until all of the simulated data is replaced to build the dataset with real-time data. In other words, if there is still simulated data present in the database, the method loops back to block 216 until all the simulated data has been replaced.

Alternatively, the dataset for use in a model for determining if a liquid is present on a roadway in real time can be generated by collecting ground truth data from the outset to create the dataset and having that initial dataset undergo dataset pre-processing to develop the model for identifying liquid on a roadway.

Once all of the simulated data has been replaced, at block 222, the data from the created virtual dataset and/or the ground truth dataset are transmitted to a neural net to assist a program in applying processing techniques, such as neural networks to learn and produce sophisticated and reliable results. The liquid obstacle database may include both simulated and ground-truth data until all of the simulated data has been replaced.

More specifically, at block 224, data from either the virtual dataset and/or the ground truth dataset undergo a data analysis and processing. In one exemplary arrangement, the data is arranged in a tabulated form in a pre-production cloud computer environment that processing equipment may access in block 224. Selected data characteristics act as a primary key (for example, a time stamp), and other data sources like CAN data, GPS position, and sensor data values are correlated to the primary key. A tabulated dataset is then sent through a telematics device and stored in the cloud 106.

At block 226, training of the neural net model is performed. In one exemplary arrangement, the training is initially supervised in block 226. For example, in connection with the method disclosed herein, through the use of the virtual dataset, training of the neural net model may begin immediately, before and during the collection of ground truth data. As a result, because the location and characteristics of the identified liquid in the virtual dataset are already known quantities, as data is fed into the neural net, the classification of the data and determinations reached on the simulated dataset can be monitored and modified.

Similarly, as ground truth data is fed into the model, during the supervised training step at block 226, correlation of physically observed liquid data may be used to verify the model's training. The supervised training step may include part of the initially collected dataset, or newly collected data, or simulation data, or any combination thereof.

Upon concluding that the supervised training of the model has met certain predetermined thresholds, in one exemplary arrangement, the method may proceed to block 228, though not required. In block 228, unsupervised training of the model continues. If no unsupervised training is utilized, then the model proceeds to block 230. In block 228, more data (e.g., raw data) is fed into the dataset, with the data being classified by predetermined rules derived from the data processing block 224. In one exemplary arrangement, the model will utilize a feature vector as an output, wherein the model will recognize consistent vector representations of the liquid objects to identify those objects. In one exemplary arrangement, artificial intelligence may be implemented to develop the model. The method then proceeds to block 232.

In block 232 a model validation operation is performed to confirm the viability as a model. More specifically, the results from the model with respect to a predetermined location from block 224 are then compared with previously collected “ground truth” data to verify viability of the model. For example, in one exemplary arrangement, the model determines its own key performance indicators (KPIs) after the processing the data, i.e., ground truth road classification of a known traveled surface on a roadway was identified as having a liquid on the roadway during an observed or controlled data collection. A determination is made to verify if the results obtained from the model are within predetermined acceptable limits, in which case the model is considered to be “trained” and ready for implementation.

In one example, the KPIs may include speeds, light conditions, amount of water, distance away, etc. A reasonable validated data set may be more than 7 mm of water-on-road at 50 km/hr. and 10 m away. Further, the ability to detect water-on-road in an opposite lane of a 2-way road may be required. Such data should be sufficient in order to ensure the integrity of the model. The predefined accuracy thresholds or acceptable limits may be for a combination of data (e.g., speed, distance, and water level), or may be for a single threshold of data such as just water level.

If the results in block 232 are not within predetermined acceptable limits, the method returns to block 230, where training of the model continues.

If the model classifies the known traveled road surface close to the actual classification of the liquid (within an acceptable deviation), then the model is considered “trained.” The method then proceeds to block 234.

Once trained, in block 234, the model may be deployed to the vehicle, i.e., the “edge,” and more specifically to a vehicle onboard computer (i.e., computing platform 110). Once deployed, in one example, as long as the vehicle is operating, the sensors 132 continue collecting ground truth data, and continuously feed the data into the model in the onboard computer. In other exemplary arrangement, the data collection may be triggered only when the vehicle reaches a certain speed of travel, where aquaplaning may occur. In yet a further exemplary arrangement, the data may also be continuously fed into dataset, continuously updating the dataset to improve its reliability.

In block 236, using the data collected by the vehicle sensors 132, the model monitors and identifies liquid obstacles on the traveled roadway. In one exemplary arrangement, the model may be configured to identify the liquid, i.e., water or oil, or identify other characteristics of the liquid, i.e., length and width of a liquid patch, depth of a liquid patch, and/or location of the liquid patch on a roadway, both in relation to a lane line. Such obstacles or obstructions are also referred to herein as water-on-road instances. Once identified, the process proceeds to block 336.

In block 236, once identification of a liquid patch or instance is accomplished, data concerning of the liquid patch may be communicated to the cloud at block 238, as well as distributed amongst a fleet of connected vehicles.

At block 240, additional data may be processed through the neural net and the model may be updated using the new data and transmitted back to the vehicle onboard computer via “over the air” technology. The method then proceeds to block 338.

When the updated model is redeployed on the vehicle onboard computer (i.e., computing platform 110), the onboard computer may utilize the data with vehicle onboard system to allow for adjustment of one or more vehicle systems (i.e., ADAS systems 130) to mitigate or prevent a potential aquaplaning event. Such mitigation may also include a remedial action in the form of instructing a vehicle system to react or behave a certain way. The remedial action may also include a driver alerts in the form of visual, haptic or audible notifications.

Referring to FIG. 3, a schematic view of a system 300 employing a model for aquaplaning detection is disclosed. The system 300 utilizes the at least one vehicle 102. As explained above, the vehicle 102 includes one more sensors 132 (not shown specifically in FIG. 3,) that may collect data indicative of the vehicle's environment. This may include image data from camera 304, vehicle CAN data 306, and location data from the GPS 308, similar to the location module 136 in FIG. 1. The vehicle 102 may collect these data sets 304, 306, 308 as the vehicle 102 is operated. The data collected may include, but are not limited to, image data 104, such as a data from a forward facing camera, vehicle CAN, and/or vehicle GPS. Other sensor data may also be collected, such as Lidar data. The sensor data or image data 104 is transmitted to an onboard computer or computing platform 110, similar to computing platform 110 of FIG. 1.

The onboard computer 110 includes a classification model 311 therein developed by process 200 discussed above. In addition, the onboard computer 110 may also include a shadow mode module 310. The shadow mode module 310 allows for data to be run through a newly deployed version of the learning model, without necessarily running the results through to other systems. In this way, the new results may be captured and stored for analysis and ultimately to improve the model.

The vehicle 102 further includes a number of operational systems 312, 314, 316, 318 that are operatively connected to the vehicle onboard computer 110. In one exemplary arrangement, such systems include a braking system 312, a traction control system 314, a stability control system 316 and a safety system 318. In addition, a driver alert system 420 may also be connected to the onboard computer 110. The vehicle systems may be used for remedial actions in response to the detection or realization of an upcoming water-on-road instance.

The braking system 312 may include systems that control the vehicle brakes, such as anti-lock braking systems (ABS). The braking systems may also include aspects of other autonomous features such as automatic parking, collision avoidance systems, etc. The traction control system 314 may aid to prevent traction loss in a vehicle around sharp turns, limit tire slip, etc. The stability control system 316 may activate brakes and reduce speed to prevent understeering or oversteering These systems may work with each other to help maintain a more stable driving experience.

The safety system 318 may include driver safety requirements such as sobriety measures, but may also include other autonomous vehicle systems to increase the overall safety of the vehicle, such as collision warnings, driver monitoring systems, speed adaptations, intersection assistants, etc.

A driver alert system 420 may include controlling alerts issued to drivers in response to certain conditions or events. These alerts may be visual, audible, haptic, etc. Some systems included for the driver alert system 420 may include a blind spot monitor system, collision warning, lane departure, parking sensors, etc. In the system herein, the driver alert system 420 may also alert the driver as to liquid objects or obstacles.

The vehicle 102 may further include a gateway 322. The gateway 322 operatively connects the vehicle onboard computer 110 with the communication network 106 and/or server cloud 108.

In one exemplary arrangement, the server cloud 108 includes a neural net 126 that is configured to process the dataset collected by the sensors 132 on the vehicle 102, and identify liquid present on roadways. In one exemplary arrangement, after processing, the processed data is utilized to create an updated or revised surface liquid classification system 328. In other words, the system 128 may be used to identify and classify liquid on a roadway, and such classification may be constantly updated, in real-time for improved accuracy. The updated surface liquid classification system 328 is directed back to the gateway 322 to update the onboard computer 110.

In another exemplary arrangement, the server cloud 108 may also be operatively connected to a vehicle fleet 330. The connected fleet 330 may be connected to the server cloud 108 through social media platforms, like crowdsourcing application such as WAZE®, or alternatively, or in addition to, may be part of a paid subscription service. The gateway 322 can be configured to send data concerning the identification of liquid on a roadway from the vehicle 102 to the fleet 330. In this manner, all of the connected vehicles in the fleet 330 may be provided with real-time information concerning the location of liquid on a roadway that may trigger an aquaplaning event. With such data, different functions of the vehicle may be trained to employ mitigation techniques, including, for example, vehicle-to-liquid parameters: presence in line with vehicle travel, time-to-engagement, etc.

Knowing these parameters, as well as other data communicated by each vehicle, i.e., speed, weight, load, dynamic, tire pressure, tire state, etc., the classification model 308 of the onboard computer 110 may communicate with the various vehicle operation systems, i.e., braking systems 312, traction control system 314, stability control system 316, and safety systems 318, such as airbag deployment and safety belt engagement locks, to take action that will mitigate or avoid an aquaplaning event. For example, in response to the data, the braking system 312 may be activated by the onboard computer 110 to automatically to reduce the speed of the vehicle 102 to avoid aquaplaning. The driver alert system 320 may provide a haptic or visual indication of a potential aquaplaning event to alert the driver to take action or to indicate that action is being taken. In those instances where due to vehicle speed or other parameters, it is not possible to alter or adjust vehicle operations in time to avoid an aquaplaning event, the vehicle safety system 318 may be actuated to trigger an airbag deployment and/or engage the safety belt in a locked position.

As further alternative exemplary arrangements, or in addition what has been described, the system 300 may further comprise additional cameras (not shown) to confirm the correct identification of liquid by a forward facing camera, lidar and/or a camera/lidar combination. More specifically, rear and side view cameras may be used to confirm the identification of a liquid patch, as well as dimensions of same as the vehicle drives over the liquid. In addition, the location of the liquid patch in a lane may be confirmed.

Crowd-sourced data may be directed into a creation of a “puddle” or standing water” map overlayed on public or subscription plan GPS services. Such “predictive puddle alerts” will provide drivers with advance notice of a potential puddle. This information can be used not only for vehicle route planning, but also become an input into a road-maintenance database and vice versa. For example, previously identified potholes and indentations on a road surface can be anticipated to become puddles during rain events.

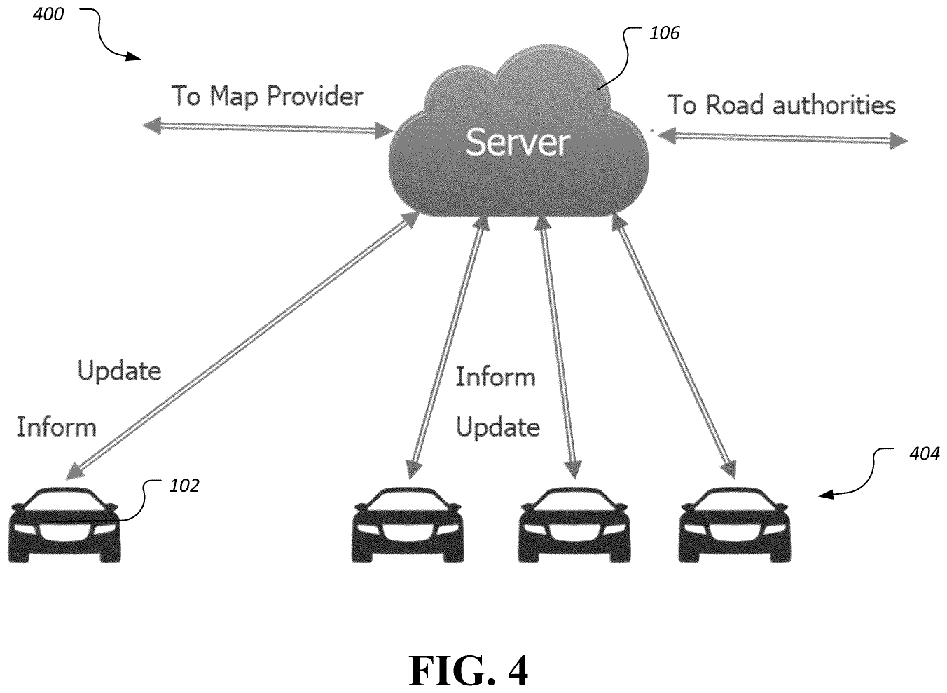

FIG. 4 is a schematic of an aquaplaning system 400 across a vehicle fleet 404. The vehicle 102 and the fleet 404 of vehicles may communicate via the server 108 in that an identified liquid obstacle may be transmitted to the cloud. Such obstacle may include the obstacle parameters such as location, size, type, etc. The server 108 may then inform other vehicles in the fleet 404 of the obstacle via real-time or near real-time updated. As the server 108 acquires the updated data regarding the obstacles, the aquaplaning model may be continually updated. In addition to the liquid obstacle database being updated, the model itself may continue to “learn.” That is, the model may become more and more accurate at detecting liquid on the roadways.

In addition to alerting the vehicle fleet of the obstacle, the data may also be used by a non-vehicle third party also in communication with the server 108, such as road commissions. Continual emergence of the “puddle”/hazard may be indicative of the road surface problem that is reported to the road authorities. If the road commission reports a repair back to the server 108, the model may update to eliminate the liquid obstacle.

Further, weather reports may be integrated into the model. If it rains a certain amount, a certain obstacle is more likely to be present than if only a small amount or rain or snow is expected. This may also increase the accuracy of remedial actions taken by vehicles approaching an expected obstacle.

Additionally, shadow data where multiple vehicles are submitting data about roads surface reflections increasing the validation and learning of the model.

The fleet 404 may include vehicles that are part of a business, or simply vehicles within a certain distance of one another that are also authorized via the server 108 to receive updated data, alerts, and models from the server 108. The fleet 404 may each subscribe to the aquaplaning model and therefore create an authorized circle of vehicles that share data in order to mitigate liquid obstacle encounters or issues arising from such encounters.

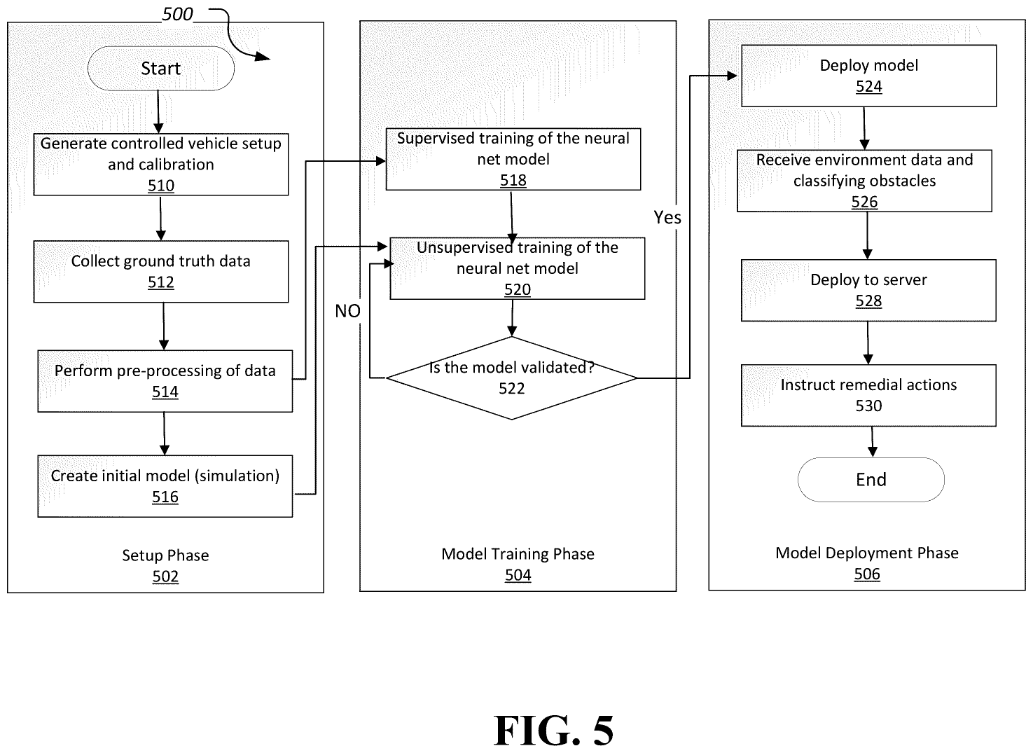

FIG. 5 is a flow chart that illustrates an example process 500 for the aquaplaning system described in FIGS. 1 and 3. The process 500 may include a setup phase 502, a model training phase 504, and a deployment phase 506.

The process 500 may being at block 510 where the vehicle calibration and set up occurs. In this example, the vehicle 102 may be calibrated with certain sensors, such as the vehicle sensors 132. A route and expected obstacles may be defined to create a test scenario or data gathering scenario for the vehicle 102. That is, a known obstacle along a known path may be established.

At block 512, the vehicle 102 may be operated along the path and ground truth data is collected from the image sensor(s) 132 and transmitted to the appropriate data processing unit (i.e., processor 112), similar to block 216 described above.

At block 514, the collected data undergoes a data pre-processing operation. More specifically, the collected data is reviewed and sanitized to “clean” the data such that the data collected corresponds to accurate readings from the sensors.

At block 516, the processor 112 may create an initial aquaplaning model (also referred to herein as the neural net model). The initial model may include generating the liquid obstacle database, as well as a learning model with expected reflection values that indicate a liquid obstacle.

At block 518, the processor 112 may perform supervised training of the model. In one exemplary arrangement, the training is initially supervised in block 226. For example, because the location and characteristics of the identified liquid in the virtual dataset are already known quantities, as data is fed into the model, the classification of the data and determinations reached on the simulated dataset can be monitored and modified. Similarly, as ground truth data is fed into the model, during the supervised training (similar to block 226), correlation of physically observed liquid data may be used to verify the model's training.

At block 520, the processor 112 may perform unsupervised training of the model. In this example a new controlled environment may be recognized and it may be unknown whether a liquid obstacle is present along a path.

AT block 522, the processor 112 may determine if the model is validated by determining the accuracy of the model. This may be done by determining if a certain sample set of determinations were correct. That is, in the event the model determined the presence of liquid, was such determination accurate. This may be done by visible inspection of the pathway at which the liquid was identified. If the accuracy is within a predefined accuracy threshold or percentage (e.g., 90% accurate,), the process 500 may proceed to block 524.

At block 524, the processor 112 may deploy the model at the vehicle, i.e., the “edge,” and more specifically to a vehicle onboard computer (i.e., computing platform 110).

At block 526, the processor 112 may receive environment data from the vehicle sensors 132 as the vehicle 102 operates. As long as the vehicle 102 is operating, the sensors 132 may continue collecting ground truth data, and continuously feed the data into the model in the onboard computer. In other exemplary arrangement, the data collection may be triggered only when the vehicle reaches a certain speed of travel, where aquaplaning may occur. In yet a further exemplary arrangement, the data may also be continuously fed into dataset, continuously updating the dataset to improve its reliability.

At block 528, the processor 112 may deploy the model to the server 108. At the server 108, the model may be updated via data from other fleet vehicles (e.g., fleet vehicles 404).

At block 528, the processor 112 may generate remedial instructions in response to detecting a liquid obstacle based on the model and the vehicle/environment data. When the updated model is redeployed on the vehicle onboard computer (i.e., computing platform 110), the onboard computer may utilize the data with vehicle onboard system to allow for adjustment of one or more vehicle systems (i.e., ADAS systems 130) to mitigate or prevent a potential aquaplaning event. Such mitigation may also include a remedial action in the form of instructing a vehicle system to react or behave a certain way. This may include effecting the vehicle operational systems such braking system 312, traction control system 314, stability control system 316 and safety system 318. The remedial action may also include a driver alerts in the form of visual, haptic or audible notifications. The process 500 may then end.

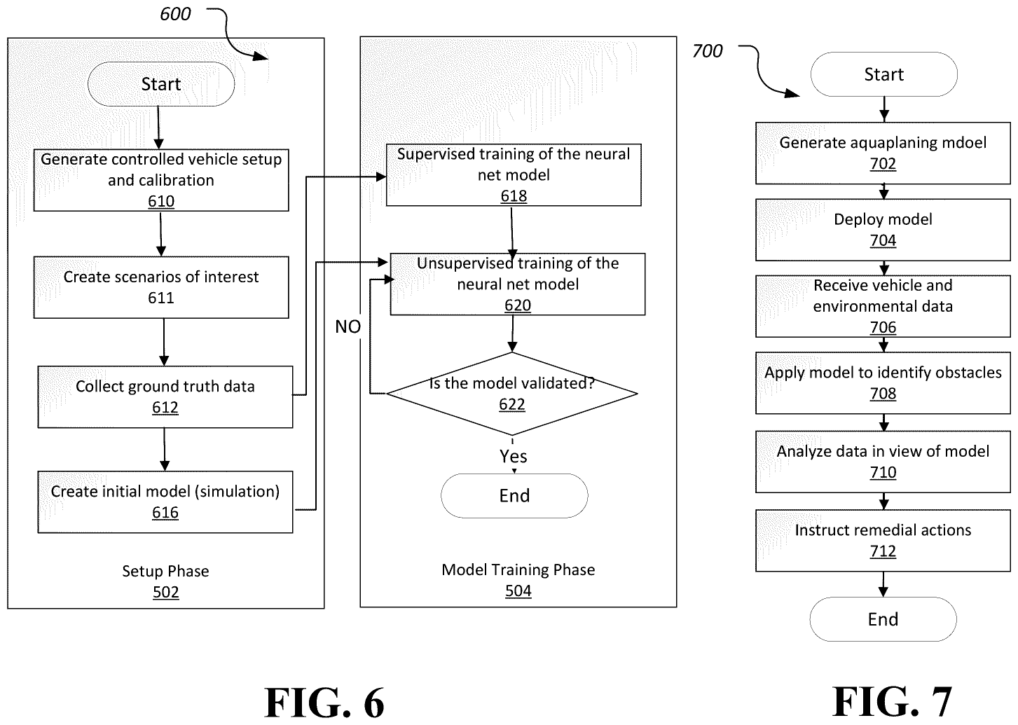

FIG. 6 is a flow chart that illustrates an example process 600 for another example of a set up and training phase of the process of FIG. 5. The process 600 may being at block 610 where the vehicle calibration and set up occurs, similar to block 510 of FIG. 5.

At block 611, the processor 112 creates scenarios that may be of interest.

At block 612, the vehicle 102 may be operated along the path and ground truth data is collected from the image sensor(s) 132 and transmitted to the appropriate data processing unit (i.e., processor 112), similar to block 512 described above.

At block 616, the processor 112 may create an initial aquaplaning model (also referred to herein as the neural net model). The initial model may include generating the liquid obstacle database, as well as a learning model with expected reflection values that indicate a liquid obstacle.

At block 618, the processor 112 may perform supervised training of the model, similar to such simulation explained above with respect to block 518.

At block 620, the processor 112 may perform unsupervised training of the model. In this example a new controlled environment may be recognized, and it may be unknown whether a liquid obstacle is present along a path.

At block 622, the processor 112 may determine if the model is validated by determining the accuracy of the model. If the accuracy is within a predefined threshold or percentage (e.g., 90% accurate,), the process 600 may end.

FIG. 7 is a flow chart that illustrates an example process for another example of a deployment phase 506 of FIG. 5. The process 700 may begin at block 702 where processor 112 creates the aquaplaning model. This model, as explained, may be continuously updated and such updated may be received from the server 108. This may be done in accordance with the processes described above, for example, the process 500 and 600.

At block 704, the model may be deployed to the vehicle 102, similar to block 524. At block 706, similar to block 526, environment data provided by the vehicle sensor 132 may be monitored in view of the model. At block 708, the processor 112 may determine whether the data indicates a liquid on the surface by applying the model.

At block 710, the processor 112 may determine whether a remedial action is necessary. This may be based on the determination that the vehicle is approaching a liquid obstacle, as well as vehicle data, such as speed, yaw, location, etc. The model may indicate an appropriate remedial action based on the known factors and parameters. Such actions may include instructing the vehicle or the driver to avoid the road, to use another lane, to alter the route, to slow down, etc.

At block 712, the processor 112 may instruct various vehicle systems to perform the remedial action or actions. The process 700 may then end.

Accordingly, a aquaplaning model is used to better the driving experience across a fleet. Identified and parameterized situation may be shared with vehicles in the vicinity as well as infrastructure such as server/cloud. Crowd-sourced data goes into the creation of “puddle” or “standing water” map overlayed on the “Google-like” maps. Mapping the puddles/standing water may become an input into the road-maintenance database and vice versa; specifically, previously identified potholes and indentations on the road surface can be anticipated to become puddles during rains.

Finally, mapping puddles can create a “predicted puddle alert” service to the drivers as long as it is not denied by other cars' observations. This alert may be pushed to vehicles within a predefined radius of the puddle that are authorized to receive updated data or alerts from the server 108. This may include the entire fleet, or only those is a certain radius or along a certain path (e.g., 1 mile away).

It is noted that the exemplary arrangements can be described as a process which is depicted as a flowchart, a flow diagram, a data flow diagram, a structure diagram, or a block diagram. Although a flowchart can describe the operations as a sequential process, many of the operations can be performed in parallel or concurrently. In addition, the order of the operations can be re-arranged. A process is terminated when its operations are completed, but could have additional steps not included in the figure. A process can correspond to a method, a function, a procedure, a subroutine, a subprogram, etc. When a process corresponds to a function, its termination corresponds to a return of the function to the calling function or the main function.

Furthermore, exemplary arrangements can be implemented by hardware, software, scripting languages, firmware, middleware, microcode, hardware description languages, and/or any combination thereof. When implemented in software, firmware, middleware, scripting language, and/or microcode, the program code or code segments to perform the necessary tasks can be stored in a machine readable medium such as a storage medium. A code segment or machine-executable instruction can represent a procedure, a function, a subprogram, a program, a routine, a subroutine, a module, a software package, a script, a class, or any combination of instructions, data structures, and/or program statements. A code segment can be coupled to another code segment or a hardware circuit by passing and/or receiving information, data, arguments, parameters, and/or memory contents. Information, arguments, parameters, data, etc. can be passed, forwarded, or transmitted via any suitable means including memory sharing, message passing, ticket passing, network transmission, etc.

For a firmware and/or software implementation, the methodologies can be implemented with modules (e.g., procedures, functions, and so on) that perform the functions described herein. Any machine-readable medium tangibly embodying instructions can be used in implementing the methodologies described herein. For example, software codes can be stored in a memory. Memory can be implemented within the processor or external to the processor. As used herein the term “memory” refers to any type of long term, short term, volatile, nonvolatile, or other storage medium and is not to be limited to any particular type of memory or number of memories, or type of media upon which memory is stored.

Moreover, as disclosed herein, the term “storage medium” can represent one or more memories for storing data, including read only memory (ROM), random access memory (RAM), magnetic RAM, core memory, magnetic disk storage mediums, optical storage mediums, flash memory devices and/or other machine readable mediums for storing information. The term “machine-readable medium” includes, but is not limited to portable or fixed storage devices, optical storage devices, wireless channels, and/or various other storage mediums capable of storing that contain or carry instruction(s) and/or data.

What have been described above are examples of the present disclosure. It is, of course, not possible to describe every conceivable combination of components or methodologies for purposes of describing the present invention, but one of ordinary skill in the art will recognize that many further combinations and permutations of the present invention are possible. While certain novel features of this disclosure shown and described below are pointed out in the annexed claims, the disclosure is not intended to be limited to the details specified, since a person of ordinary skill in the relevant art will understand that various omissions, modifications, substitutions and changes in the forms and details of the disclosure illustrated and in its operation may be made without departing in any way from the spirit of the present disclosure. Accordingly, the present disclosure is intended to embrace all such alterations, modifications, and variations that fall within the scope of the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements. No feature of the disclosure is critical or essential unless it is expressly stated as being “critical” or “essential.”

What is claimed is:

1. A method of developing an aquaplaning mitigation model, comprising:
receiving ground truth data from at least one vehicle sensor concerning detected liquid obstacles on a physical roadway by performing an initial vehicle operation over the physical roadway;
generating an initial aquaplaning model based on the ground truth data;
receiving subsequent environment data from the at least one vehicle sensor;
determining whether the subsequent environment data indicates a liquid obstacle;
applying supervised training of the aquaplaning model based on the ground truth data and unsupervised training based on the subsequent environment data; and
validating the aquaplaning model based on a predefined accuracy threshold.

2. The method of claim 1, wherein the receiving of the ground truth data includes detecting liquid obstacles including each of water, oil, snow, and ice.

3. The method of claim 1, wherein the ground truth data and environment data include light reflection detected by the at least one vehicle sensor and wherein the model determines whether the ground truth data or environment data indicated a liquid obstacle based on the light reflection.

4. The method of claim 3, wherein the model determines whether the light reflection indicates a liquid obstacle based on an expected reflection for a time of day.

5. The method of claim 1, further comprising generating a liquid obstacle database based on the model, the liquid obstacle database including at least one liquid obstacle.

6. The method of claim 5, wherein the detected liquid obstacle includes parameters associated with the at least one liquid obstacle, the parameters including at least one of a size and depth of the detected liquid obstacle.

7. The method of claim 1, further comprising receiving operational information from vehicle systems separate from the image data.

8. The method of claim 7, wherein the additional operational information includes vehicle controller area network (CAN) data and vehicle global positioning system (GPS) data containing vehicle data.

9. The method of claim 8, further comprising generating a remedial action during operation of the vehicle in response to the model indicating an upcoming presence of a liquid obstacle and the vehicle data.

10. The method of claim 8, wherein the vehicle data includes at least one of vehicle speed, weight, load, tire pressure and state.

11. The method claim 9 wherein the remedial action includes an alert including at least one of a haptic, visual, or audible alert.

12. The method of claim 9, wherein the remedial action includes sending instructions to at least one vehicle systems to mitigate the effect of aquaplaning.

13. The method of claim 11, wherein the vehicle systems include at least one of braking systems, traction control systems, stability control system, steering system, and safety systems.

14. A method for mitigating aquaplaning in a vehicle, comprising:
deploying an aquaplaning model to a vehicle;
receiving environment data from at least one vehicle sensor during operation of the vehicle;
determining whether at least one liquid obstacle is identified by applying the aquaplaning model to the environment data; and
generating a remedial action in response to the model indicating an upcoming presence of a liquid obstacle.

15. The method claim 14, wherein the remedial action includes an alert including at least one of a haptic, visual, or audible alert.

16. The method of claim 14, wherein the remedial action includes sending instructions to at least one vehicle systems to mitigate the effect of aquaplaning, wherein the vehicle systems include at least one of braking systems, traction control systems, stability control system and safety systems.

17. The method of claim 14, further comprising transmitting the indication of the at least one obstacle to a server external to the vehicle.

18. The method of claim 17, wherein the server cloud is operatively connected to at least one vehicle in a predefined radius of the at least one obstacle to transmit an indication of the at least one obstacle to the at least one vehicle within the predefined radius.

19. A method for updating an aquaplaning model across a group of vehicles, comprising:
receiving an aquaplaning model capable of determining whether a liquid obstacle is detected along a vehicle route;
receiving updated vehicle data from at least one vehicle from the group of vehicles; and
updating the aquaplaning model with the updated vehicle data; and
transmitting the updated aquaplaning model to the other of the vehicles in the group of vehicles.

20. The method of claim 19, wherein the updated vehicle data indicates a liquid obstacle, and further comprising transmitted the liquid obstacle to at least one non-vehicle third party.
